(19) United States
(12) Patent Application Publication
(10) Pub. No.: US 2026/0303028 A1
(43) Pub. Date: Oct. 1, 2026

(54) RADIO-FREQUENCY MODULE, COMMUNICATION APPARATUS, AND CONTROL METHOD

(71) Applicant: Murata Manufacturing Co., Ltd., Nagaokakyo-shi (JP)

(72) Inventor: Kenji TAHARA, Nagaokakyo-shi (JP)

(21) Appl. No.: 19/574,512

(22) Filed: Mar. 23, 2026

(30) Foreign Application Priority Data
Mar. 26, 2025 (JP) 2025-051328

(51) Int. Cl. H03F 1/02; H03F 3/24; H04B 1/10

(52) U.S. Cl. CPC H03F 1/0288; H03F 3/245; H04B 1/10; H03F 2200/451

(57) ABSTRACT

A radio-frequency module performs transmission and reception of a signal via an antenna. In radio-frequency module, since impedance is adjusted using the switches that are not provided on the transmission path of the signal by appropriately setting the phase of the output signal from each amplifier and/or the driving state of each amplifier and the conducting state of each switch in transmission and reception, it is possible to appropriately switch between the transmission operation and the reception operation. In addition, the radio waves received as differential signals are capable of being inputted into the reception circuit in the same phase.

### CROSS REFERENCE TO RELATED APPLICATION

This application claims priority from Japanese Patent Application No. 2025-051328, filed on Mar. 26, 2025. The content of this application is incorporated herein by reference in its entirety.

### BACKGROUND OF THE DISCLOSURE

### 1. Field of the Disclosure

The present disclosure relates to a radio-frequency module, a communication apparatus, and a control method. More particularly, the present disclosure relates to a technique to improve reception efficiency while keeping the isolation between a transmission circuit and a reception circuit in a communication circuit that performs transmission and reception using a common radiation element.

### 2. Description of the Related Art

U.S. Pat. No. 10,715,204 discloses an electronic device that performs transmission and reception of radio-frequency radio waves using a common radiation element. The electronic device in U.S. Pat. No. 10,715,204 is configured so that a power amplifier for transmission and a low-noise amplifier for reception are provided for a shared antenna and a transmission circuit and a reception circuit are switched using switches.

### BRIEF SUMMARY OF THE DISCLOSURE

The electronic device disclosed in U.S. Pat. No. 10,715,204 has a configuration in which coupling between the transmission and the reception is switched using semiconductor switches that are connected in parallel to a magnetically-coupled transformer. In such a configuration, even when the switches are in a non-conducting state, part of the radio-frequency signal may leak due to parasitic capacitance that inevitably occurs at the switches to reduce isolation characteristics between the transmission circuit and the reception circuit. In addition, if the reception efficiency is reduced in the reception circuit disclosed in U.S. Pat. No. 10,715,204, packet loss and so on is likely to occur.

In order to resolve the above problems, it is a possible benefit of the present disclosure to improve the reception efficiency while keeping the isolation between a transmission circuit and a reception circuit in a radio-frequency module that performs transmission and reception using a common antenna.

A radio-frequency module according to an embodiment of the present disclosure performs transmission and reception of a signal via an antenna. The radio-frequency module includes a first terminal and a second terminal; a third terminal and a fourth terminal, which are connected to the antenna; a first amplifier having an input terminal electrically connected to the first terminal; a second amplifier having an input terminal electrically connected to the first terminal; a third amplifier having an output terminal connected to the second terminal; a first transmission line which is connected between an output terminal of the first amplifier and an output terminal of the second amplifier and which has a length of ¼ of a wavelength of the signal; a second transmission line which is connected to the output terminal of the first amplifier and which has a length of ¼0 of the wavelength of the signal; a third transmission line which has a first end connected to the second transmission line and a second end connected to the third terminal and which has a length of ½ of the wavelength of the signal; a fourth transmission line which is connected to the output terminal of the second amplifier and which has a length of ¼ of the wavelength of the signal; a fifth transmission line which has a first end connected to the fourth transmission line and a second end connected to the fourth terminal and which has a length of ¼ of the wavelength of the signal; a sixth transmission line which is connected between the first end of the third transmission line and the first end of the fifth transmission line and which has a length of ¼ of the wavelength of the signal; a seventh transmission line which is connected between an input terminal of the third amplifier and the first end of the fifth transmission line and which has a length of ¼ of the wavelength of the signal; a first switch connected between the output terminal of the first amplifier and ground; and a second switch connected between the output terminal of the second amplifier and the ground.

A control method according to an embodiment of the present disclosure is used in a radio-frequency module that performs transmission and reception of a radio-frequency signal via an antenna. The radio-frequency module includes a first terminal and a second terminal; a third terminal and a fourth terminal, which are connected to the antenna; a first amplifier having an input terminal electrically connected to the first terminal; a second amplifier having an input terminal electrically connected to the first terminal; a third amplifier having an output terminal connected to the second terminal; a first transmission line which is connected between an output terminal of the first amplifier and an output terminal of the second amplifier and which has a length of ¼ of a wavelength of the signal; a second transmission line which is connected to the output terminal of the first amplifier and which has a length of ¼ of the wavelength of the signal; a third transmission line which has a first end connected to the second transmission line and a second end connected to the third terminal and which has a length of ½ of the wavelength of the signal; a fourth transmission line which is connected to the output terminal of the second amplifier and which has a length of ¼ of the wavelength of the signal; a fifth transmission line which has a first end connected to the fourth transmission line and a second end connected to the fourth terminal and which has a length of ½ of the wavelength of the signal; a sixth transmission line which is connected between the first end of the third transmission line and the first end of the fifth transmission line and which has a length of ¼ of the wavelength of the signal; a seventh transmission line which is connected between an input terminal of the third amplifier and the first end of the fifth transmission line and which has a length of ¼ of the wavelength of the signal; a first switch connected between the output terminal of the first amplifier and ground; and a second switch connected between the output terminal of the second amplifier and the ground. The control method includes setting each of the first switch and the second switch to a conducting state when the signal supplied from each of the third terminal and the fourth terminal is supplied to the input terminal of the third amplifier, and setting each of the first switch and the second switch to a non-conducting state when the signal outputted from each of the first amplifier and the second amplifier is outputted to the third terminal.

In the radio-frequency module according to the present disclosure, since impedance is adjusted using the switches that are not provided on the transmission path of the signal by appropriately setting the phase of the output signal from each amplifier and/or the driving state of each amplifier and the conducting state of each switch in transmission and reception, it is possible to appropriately switch between the transmission operation and the reception operation. In addition, the radio waves received as differential signals are capable of being inputted into the reception circuit in the same phase. Accordingly, in the radio-frequency module performing the transmission and the reception using the common antenna, it is possible to improve the reception efficiency while keeping the isolation between the transmission circuit and the reception circuit.

### BRIEF DESCRIPTION OF THE SEVERAL VIEWS OF THE DRAWINGS

FIG. 1 is a diagram schematically illustrating the configuration of a communication apparatus to which a radio-frequency module according to an embodiment is applied;

FIG. 2 is a diagram for describing a detailed configuration of a power amplifier circuit;

FIG. 3 is a diagram for describing reception of radio waves at an antenna;

FIG. 4 is a diagram for describing a signal path in a reception mode;

FIG. 5 is a diagram for describing the signal path in a first transmission mode;

FIG. 6 includes diagrams for describing the operation of a Doherty amplifier;

FIG. 7 is a diagram for describing transmission of the radio waves in the first transmission mode;

FIG. 8 is a diagram for describing the signal path in a second transmission mode;

FIG. 9 is a diagram for describing the transmission of the radio waves in the second transmission mode; and

FIG. 10 is a diagram illustrating a flowchart of a process performed in a signal processing circuit.

### DETAILED DESCRIPTION OF DISCLOSURE

Embodiments of the present disclosure will herein be described in detail with reference to the drawings. The same reference numerals and letters are used in the drawings to identify the same components or similar components and description of such components is not repeated.

### FIRST EMBODIMENT

### Entire Configuration of Communication Apparatus

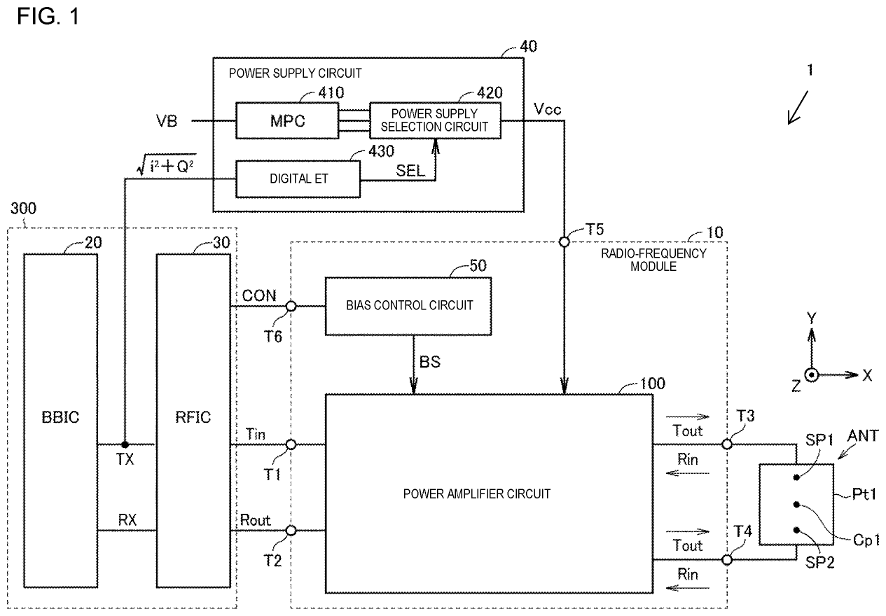

FIG. 1 is a diagram schematically illustrating the configuration of a communication apparatus 1 to which a radio-frequency module 10 according to an embodiment is applied. The communication apparatus 1 is, for example, a mobile terminal, such as a mobile phone, a smartphone, or a tablet, a personal computer having a communication function, a base station, or the like.

Referring to FIG. 1, the communication apparatus 1 includes an antenna ANT, the radio-frequency module 10, a signal processing circuit 300, and a power supply circuit 40. The radio-frequency module 10 includes terminals T1 to T6, a bias control circuit 50, and a power amplifier circuit 100. The signal processing circuit 300 includes a baseband integrated circuit (BBIC) 20 and a radio-frequency integrated circuit (RFIC) 30.

The communication apparatus 1 schematically up-converts a transmission signal TX, which is an intermediate-frequency signal transmitted from the BBIC 20, to a radio-frequency (RF) signal in the RFIC 30 and amplifies the radio-frequency signal in the power amplifier circuit 100 to radiate the radio-frequency signal from the antenna ANT. In addition, the communication apparatus 1 amplifies a radio-frequency signal received with the antenna ANT with low noise in the power amplifier circuit 100 and down-converts the radio-frequency signal into an intermediate-frequency signal in the RFIC 30 to transmit the intermediate-frequency signal to the BBIC 20 as a reception signal RX.

The RFIC 30 is an example of a signal processing circuit that processes the radio-frequency signal. The RFIC 30 up-converts the intermediate-frequency signal transmitted from the BBIC 20 to the radio-frequency signal and supplies the generated radio-frequency signal to the radio-frequency module 10 via the terminal T1. In addition, the RFIC 30 receives a radio-frequency signal received at the antenna ANT from the radio-frequency module 10 via the terminal T2.

The bias control circuit 50 receives a control signal CON from the RFIC 30 via the terminal T6. The bias control circuit 50 generates a bias signal BS based on the control signal CON to supply the bias signal BS to the power amplifier circuit 100. The bias signal BS is a signal for controlling the magnitude and the supply timing of bias current at amplifiers included in the power amplifier circuit 100.

The power amplifier circuit 100 amplifies an input signal Tin received from the RFIC 30 via the terminal T1 to generate an output signal Tout and supplies the output signal Tout to the antenna ANT. In addition, the power amplifier circuit 100 amplifies a radio-frequency signal Rin received at the antenna ANT to generate an output signal Rout and supplies the output signal Rout to the RFIC 30 via at least one of the terminal T3 and the terminal T4.

The antenna ANT is, for example, a patch antenna having a plate-shaped radiation electrode Pt1. The terminals T3 and T4 of the radio-frequency module 10 are connected to feeding points SP1 and SP2, respectively, of the antenna ANT with feeding lines. The normal direction of the radiation electrode Pt1 (the radiation direction of radio waves) is hereinafter defined as the positive direction of the Z axis and planes orthogonal to the Z-axis direction are hereinafter defined as the X axis and the Y axis.

The feeding point SP1 is offset from the center of the radiation electrode Pt1 in the positive direction of the Y axis. The feeding point SP2 is offset from the center of the radiation electrode Pt1 in the negative direction of the Y axis. Accordingly, upon supply of the output signal Tout, which is the radio-frequency signal outputted from the radio-frequency module 10, to the feeding point SP1 or the feeding point SP1, the antenna ANT is capable of radiating the radio waves, the polarization direction of which is the Y-axis direction, to the normal direction of the radiation electrode Pt1. In addition, the antenna ANT receives the radio waves from the space, the polarization direction of which is the Y-axis direction, and converts the radio waves into an electric signal to supply the electric signal to the power amplifier circuit 100 as the input signal Rin. As described below, the antenna ANT is configured so as to be capable of converting differential signals, the polarization direction of which is the Y-axis direction, into signals of the same phase to amplify the signals.

The power supply circuit 40 is an example of a so-called digital tracker and is capable of supplying power supply voltage Vcc having multiple different voltage levels to the power amplifier circuit 100. The power supply circuit 40 includes a multilevel power converter (MPC) 410, a power supply selection circuit 420, and a digital envelope tracker (ET) 430.

The MPC 410 includes multiple direct-current (DC)-direct-current (DC) converters, although not illustrated in FIG. 1. The MPC 410 converts battery voltage VB supplied from an external battery into multiple different voltage levels to supply the battery voltage VB of the multiple different voltage levels to the power supply selection circuit 420.

The digital ET 430 receives an IQ signal of the transmission signal from the BBIC 20 to track the envelope of the transmission signal in a digital ET mode. The digital ET 430 generates a selection signal SEL corresponding to the voltage level of the envelope of the transmission signal to supply the selection signal SEL to the power supply selection circuit 420.

The power supply selection circuit 420 selects the voltage corresponding to the selection signal SEL from the multiple voltage levels supplied from the MPC 410 to supply the voltage to the power amplifier circuit 100 as the power supply voltage Vcc via the terminal T5.

### Detailed Configuration of Power Amplifier Circuit

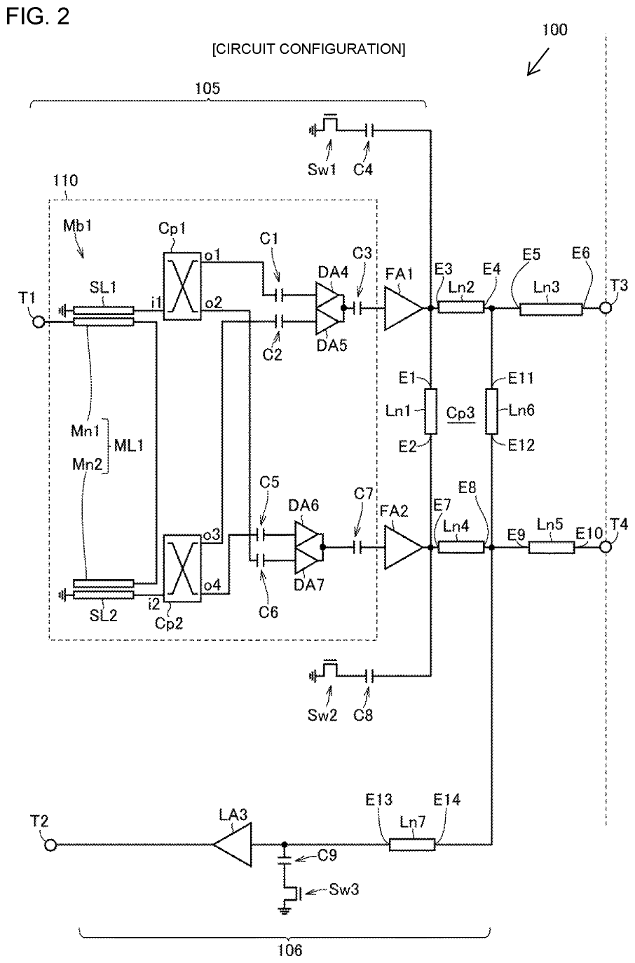

A detailed configuration of the power amplifier circuit 100 in the radio-frequency module 10 will now be described. FIG. 2 is a diagram for describing the detailed configuration of the power amplifier circuit 100.

The power amplifier circuit 100 includes a transmission circuit 105, a reception circuit 106, and a hybrid coupler Cp3. The transmission circuit 105 includes a phase adjustment circuit 110, amplifiers FA1 and FA2, switches Sw1 and Sw2, and capacitors C4 and C8. The reception circuit 106 includes a low-noise amplifier (LNA) LA3, a line Ln7, a switch Sw3, and a capacitor C9.

The configuration included in the power amplifier circuit 100 along a signal path of the power amplifier circuit 100 in transmission will be described. The transmission signal inputted into the terminal T1 is inputted into the phase adjustment circuit 110. The phase adjustment circuit 110 is configured so as to be capable of adjusting the phases of two transmission signals to be supplied to the amplifiers FA1 and FA2. The phase adjustment circuit 110 includes a balun Mb1, hybrid couplers Cp1 and Cp2, capacitors C1 to C3 and C5 to C7, and amplifiers DA4 to DA7.

The transmission signal inputted into the terminal T1 is first supplied to the balun Mb1 included in the phase adjustment circuit 110. The balun Mb1 is a so-called merchant balun in which two sub-lines SL1 and SL2 having a length of ¼ of a wavelength λ (λ/4) are coupled to a main line ML1 having a length of λ/2. In such a merchant balun, the lengths of the main line ML1 and the sub-lines SL1 and SL2 are appropriately set in accordance with a center frequency (λ) of the passband of the balun Mb1. It is sufficient for the electrical length of the main line ML1 to be approximately λ/2 and it is sufficient for the electrical length of the sub-lines SL1 and SL2 to be approximately λ/4. The same applies to the electrical length of each line described below.

In the balun Mb1, the main line ML1 functions as an unbalanced terminal and the sub-lines SL1 and SL2 function as a pair of balanced terminals. The main line ML1 has a configuration in which a line Mn1 is connected in series to a line Mn2. When the waveform of the passing radio-frequency signal is denoted by λ, each of the sub-lines SL1 and SL2 and the lines Mn1 and Mn2 has an electrical length of λ/4.

In the first embodiment, the balun Mb1 converts an unbalanced signal inputted into the terminal T1 into balanced signals (the differential signals) to supply the balanced signals to the hybrid couplers Cp1 and Cp2. As illustrated in FIG. 2, one end of the sub-line SL1 is connected to an input terminal i1 of the hybrid coupler Cp1. The other end of the sub-line SL1 is grounded. One end of the sub-line SL2 is connected to an input terminal i2 of the hybrid coupler Cp2. The other end of the sub-line SL2 is grounded.

One end of the line Mn1 included in the main line ML1 is connected to the terminal T1. The other end of the line Mn1 is connected to the line Mn2. The sub-line SL1, which is a balanced line, is disposed side by side with the line Mn1, which is part of the main line ML1, which is an unbalanced line. The sub-line SL1 is line-coupled to the line Mn1. Similarly, the sub-line SL2, which is a balanced line, is disposed side by side with the line Mn2, which is part of the main line ML1, which is an unbalanced line. The sub-line SL2 is line-coupled to the line Mn2.

The transmission signal inputted from the terminal T1 is inputted into the sub-lines SL1 and SL2 via the lines Mn1 and Mn2, respectively. At this time, the phase of the signal transmitted to the sub-line SL2 is inverted due to inversion of the moving direction and has a phase opposite to that of the signal transmitted to the sub-line SL1. Accordingly, the differential signals are inputted into the input terminals i1 and i2.

The hybrid coupler Cp1 receives the signal at the input terminal i1 and outputs two transmission signals having a phase difference of 90° from two output terminals o1 and o2. The hybrid coupler Cp2 also receives the signal at the input terminal i2 and outputs two transmission signals having a phase difference of 90° from two output terminals o3 and o4. As illustrated in FIG. 2, input terminals of the amplifiers DA4, DA7, DA5, and DA6 are connected to the output terminals o1, o2, o3, and o4 via the capacitors C1, C6, C2, and C5, respectively.

Output terminals of the amplifiers DA4 and DA5 are connected to an input terminal of the amplifier FA1 via the capacitor C3. The amplifier FA1 amplifies the signal supplied from one of the amplifiers DA4 and DA5. Output terminals of the amplifiers DA6 and DA7 are connected to an input terminal of the amplifier FA2 via the capacitor C7. The amplifier FA2 amplifies the signal supplied from one of the amplifiers DA6 and DA7. In the phase adjustment circuit 110, the amplifiers supplying the signals to the amplifiers FA1 and FA2 are switched by controlling the driving states of the amplifiers DA4 to DA7 to adjust the phases of the signals to be supplied to the amplifiers FA1 and FA2.

Output terminals of the amplifiers FA1 and FA2 are connected to input terminals of the hybrid coupler Cp3. As illustrated in FIG. 2, the hybrid coupler Cp3 includes lines Ln1, Ln2, Ln4, and Ln6, which are connected to each other in an annular shape. Each of the lines Ln1, Ln2, Ln4, and Ln6 has an electrical length of λ/4.

An end portion E1 of the line Ln1 is connected to the output terminal of the amplifier FA1. An end portion E2 of the line Ln1 is connected to the output terminal of the amplifier FA2. In other words, the line Ln1 is connected between the output terminal of the amplifier FA1 and the output terminal of the amplifier FA2.

An end portion E3 of the line Ln2 is connected to the output terminal of the amplifier FA1. An end portion E4 of the line Ln2 is connected to an end portion E5 of the line Ln3. An end portion E6 of the line Ln3 is connected to the terminal T3. In other words, the line Ln2 is connected between the output terminal of the amplifier FA1 and the terminal T3. The line Ln3 has an electrical length of λ/2.

Similarly, an end portion E7 of the line Ln4 is connected to the output terminal of the amplifier FA2. An end portion E8 of the line Ln4 is connected to an end portion E9 of the line Ln5. An end portion E10 of the line Ln5 is connected to the terminal T4. In other words, the line Ln4 is connected between the output terminal of the amplifier FA2 and the terminal T4. The line Ln5 has an electrical length of λ/4.

An end portion E11 of the line Ln6 is connected to the end portion E4 of the line Ln2. An end portion E12 of the line Ln6 is connected to the end portion E8 of the line Ln4. In other words, the line Ln6 is connected between the line Ln2 and the line Ln4.

As illustrated in FIG. 2, the output terminal of the amplifier FA1 is grounded via the capacitor C4 and the switch Sw1. The output terminal of the amplifier FA2 is grounded via the capacitor C8 and the switch Sw2.

The reception circuit 106 will now be described. An end portion E14 of the line Ln7 included in the reception circuit 106 is connected to the terminal T4 via the line Ln5. The end portion E14 of the line Ln7 is connected to the terminal T3 via the lines Ln3 and Ln6. An end portion E13 of the line Ln7 is connected to an input terminal of the low-noise amplifier LA3. The line Ln7 has an electrical length of λ/4. An output terminal of the low-noise amplifier LA3 is connected to the terminal T2. The input terminal of the low-noise amplifier LA3 is grounded via the capacitor C9 and the switch Sw3.

The radio-frequency module 10 of the first embodiment is configured so as to be capable of being controlled in a reception mode, a first transmission mode, and a second transmission mode. The reception mode is a mode in which, after the reception signal inputted from the terminal T3 is adjusted so as to be in phase with the reception signal inputted from the terminal T4, the reception signal is amplified in the low-noise amplifier LA3 and the amplified reception signal is supplied from the terminal T2 to the RFIC 20.

The first transmission mode is a mode in which the amplifiers FA1 and FA2 and the line Ln1 are caused to function as a Doherty amplifier and the transmission signal is outputted from the terminal T3. The second transmission mode is a mode in which the amplifiers FA1 and FA2 are caused to operate at maximum output and the transmission signal is outputted from the terminal T4.

### Reception Mode

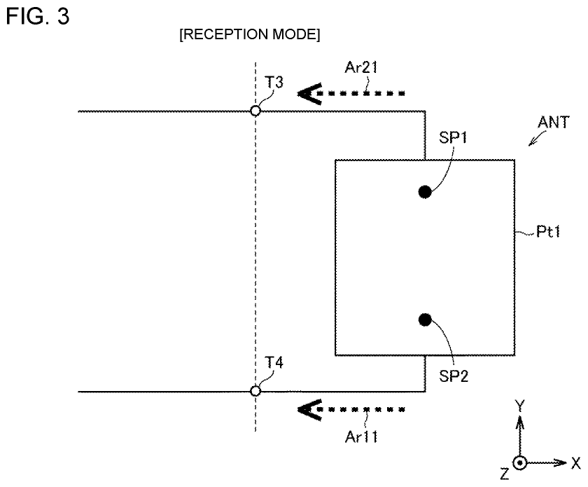

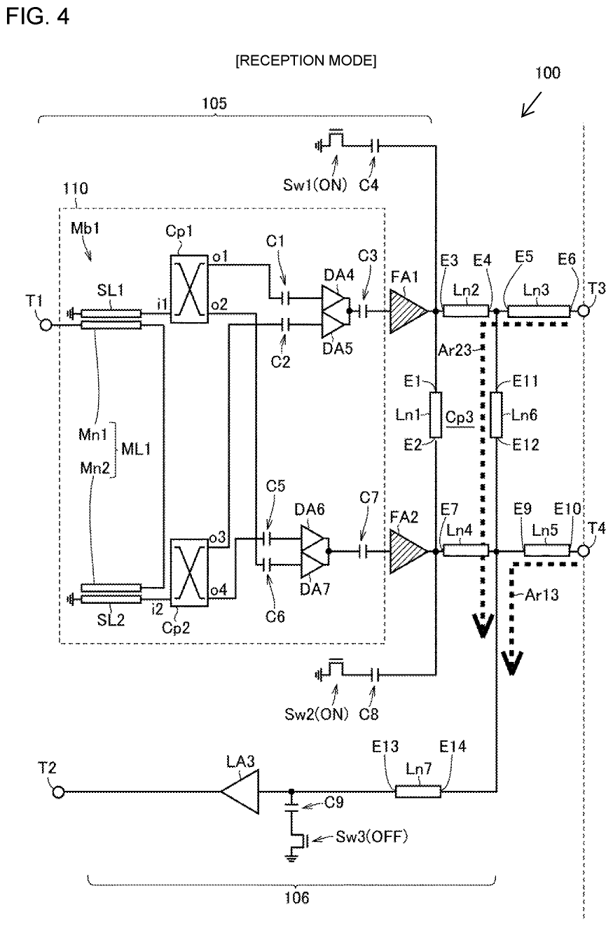

The reception mode will now be described with reference to FIG. 3 and FIG. 4. FIG. 3 is a diagram for describing reception of the radio waves at the antenna ANT. As described above, the feeding points SP1 and SP2 of the antenna ANT are disposed at positions offset from the center in the opposite directions. Accordingly, the antenna ANT is capable of concurrently receiving the radio waves of a first phase and the radio waves of a second phase opposite to the first phase.

When the antenna ANT receives the radio waves of the first phase via the feeding point SP1, the antenna ANT receives the radio waves of the second phase via the feeding point SP2. The reception signal of the first phase is inputted into the terminal T3, as illustrated by an arrow Ar21, and the reception signal of the second phase is inputted into the terminal T4, as illustrated by an arrow Ar11. The phase of the reception signal inputted into the terminal T3 is opposite to the phase of the reception signal inputted into the terminal T4.

FIG. 4 is a diagram for describing the signal path in the reception mode. In the radio-frequency module 10, in the reception mode, the switches Sw1 and Sw2 are controlled so as to be in a conducting state and the switch Sw3 is controlled so as to be in a non-conducting state. The amplifiers FA1 and FA2 are controlled so as to be in a non-driven state.

As illustrated in FIG. 4, the line Ln2 having an electrical length of λ/4 is connected in series between the end portion E5 of the line Ln3 and ground potential. An inductive component of the line Ln 2 rotates impedance clockwise by 180 degrees on a Smith chart. Accordingly, when the switch Sw1 connected to the ground potential is controlled so as to be in the conducting state, the impedance when the line Ln2 side is viewed from the end portion E5 is in an open state through the line Ln2. In other words, the reception signal inputted from the terminal T3 is inhibited from being transmitted from the end portion E5 to the line Ln2 and is prompted to be transmitted to the line Ln6, as illustrated by an arrow Ar23.

Similarly, the line Ln4 having an electrical length of λ/4 is connected in series between the end portion E9 of the line Ln5 and the ground potential. Since the line Ln4 also functions as the impedance inverter, like the line Ln2, the impedance when the line Ln4 side is viewed from the end portion E9 and the impedance when the line Ln4 side is viewed from the end portion E12 are in the open state. The reception signal inputted from the terminal T4 is inhibited from being transmitted from the end portion E9 to the line Ln4 and is prompted to be transmitted to the line Ln7, as illustrated by an arrow Ar13. Similarly, the reception signal inputted from the terminal T3 is inhibited from being transmitted from the end portion E12 to the line Ln4 and is prompted to be transmitted to the line Ln7, as illustrated by the arrow Ar23.

Transition of the phases of the reception signals inputted from the terminals T3 and T4 will now be described. Since the line Ln3 has an electrical length of approximately ½ of the wavelength, the phase of the signal is delayed by about 180° upon passing of the reception signal inputted from the terminal T3 through the line Ln3. In addition, since the line Ln6 has a line length of approximately ¼ of the wavelength, the phase of the signal is delayed about 90° upon passing of the reception signal that has passed through the line Ln3 through the line Ln6. In other words, the reception signal that passes through the path indicated by the arrow Ar23 and that is inputted into the terminal T3 is delayed by about 270° before the reception signal is transmitted to the line Ln7.

Since the line Ln 5 has a line length of approximately ¼0 of the wavelength, the phase of the signal is delayed by about 90° upon passing of the reception signal inputted from the terminal T4 through the line Ln5. In other words, the reception signal that passes through the path indicated by the arrow Ar13 and that is inputted into the terminal T4 is delayed by about 90° before the reception signal is transmitted to the line Ln7. The phase of the reception signal inputted into the terminal T3 is opposite to the phase of the reception signal inputted into the terminal T4, as described above. Accordingly, the reception signals inputted into the terminals T3 and T4 are in phase with each other at the stage at which the reception signals are transmitted to the line Ln7 because the phases of the reception signals are adjusted through the lines Ln3, Ln5, and Ln6. Consequently, in the radio-frequency module 10 of the first embodiment, in the reception mode, since it is possible to combine the two radio waves having the opposite phases, which are transmitted from the antenna ANT, with each other and receive the combined radio waves, reception efficiency is improved, compared with a case in which the radio wave is received from one feeding point. In addition, in the radio-frequency module 10 of the first embodiment, the isolation between the transmission circuit and the reception circuit is realized through the impedance adjustment by each line.

### First Transmission Mode

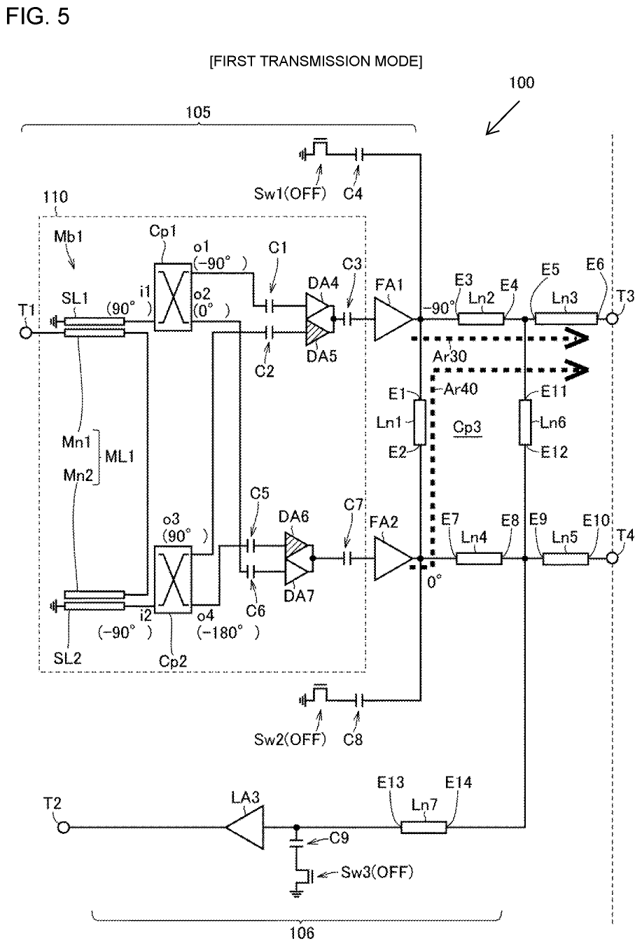

The first transmission mode will now be described with reference to FIG. 5 to FIG. 7. FIG. 5 is a diagram for describing the signal path in the first transmission mode. In the radio-frequency module 10, in the first transmission mode, each of the switches Sw1, Sw2, and Sw3 is controlled so as to be in the non-conducting state. Each of the amplifiers DA4 and DA7 is controlled so as to be in a driven state while each of the amplifiers DA5 and DA6 is controlled so as to be in the non-driven state. Accordingly, in the first transmission mode, the amplifiers FA1 and FA2 and the line Ln1 function as the Doherty amplifier. More specifically, the amplifier FA1 functions as a peak amplifier and the amplifier FA2 functions as a carrier amplifier.

In the first embodiment, a class A amplifier or a class AB amplifier, which has relatively small distortion, is used as the amplifier FA2. The amplifier FA2 amplifies the input signal supplied from the amplifier DA4 using the power supply voltage VCC supplied from a power supply terminal (not illustrated). The line Ln1 adjusts the phase of the signal amplified by the amplifier FA2. The line Ln1 is capable of delaying the phase of the signal amplified by the amplifier FA2 by 90°. In addition, the line Ln 1 is capable of rotating the impedance by 180° on the Smith chart, as described above. In other words, the line Ln1 also functions as the impedance inverter.

In the first embodiment, for example, a class C amplifier is used as the amplifier FA1. The use of the class C amplifier causes the amplifier FA1 to stop the amplification operation if the voltage level of the input signal is lower than or equal to a predetermined value. The amplifier FA1 amplifies the input signal supplied from the amplifier DA7 using the power supply voltage VCC supplied from the power supply terminal (not illustrated). The amplifier FA2 may include multiple amplifiers. Similarly, the amplifier FA1 may include multiple amplifiers.

A transmission path of the signal in the first transmission mode will now be described. The lines Ln4 and Ln7 are connected in series between the output terminal of the amplifier FA2 and the ground potential. The inductive components of the lines Ln4 and Ln7 rotate the impedance clockwise by 360 degrees on the Smith chart. Accordingly, when the switch Sw3 connected to the ground potential is controlled so as to be in the non-conducting state, the impedance when the line Ln4 side is viewed from the output terminal of the amplifier FA2 is in the open state through the lines Ln4 and Ln7. In other words, the transmission signal outputted from the output terminal of the amplifier FA2 is inhibited from being transmitted from the output terminal of the amplifier FA2 to the line Ln4 and is prompted to be transmitted to the line Ln1, as illustrated by an arrow Ar40.

Similarly, the lines Ln6 and Ln7 are connected in series between the end portion E4 and the ground potential. Accordingly, when the switch Sw3 connected to the ground potential is controlled so as to be in the non-conducting state, the impedance when the line Ln6 side is viewed from the end portion E4 is in the open state through the lines Ln6 and Ln7. In other words, the transmission signal outputted from the output terminal of the amplifier FA1 is inhibited from being transmitted from the end portion E4 to the line Ln6 and is prompted to be transmitted to the line Ln3, as illustrated by an arrow Ar30. Similarly, the transmission signal outputted from the output terminal of the amplifier FA2 is inhibited from being transmitted from the end portion E4 to the line Ln6 and is prompted to be transmitted to the line Ln3, as illustrated by the arrow Ar40. In addition, the lines Ln5 and Ln7 also function as the impedance inverters to suppress the transmission of the signal from the antenna ANT side to the terminal T4.

The transition of the phase in the first transmission mode will now be described. The signal inputted into the terminal T1 is outputted with a phase difference of 180° through the balun Mb1. For example, the signal of a phase of 90° is inputted into the input terminal i1 and the signal of a phase of −90° is inputted into the input terminal i2. Then, the signal of a phase of −90° is outputted from the output terminal o1 and the signal of a phase of 0° is outputted from the output terminal o2 through the hybrid coupler Cp1. The signal of a phase of 90° is outputted from the output terminal o3 and the signal of a phase of −180° is outputted from the output terminal o4 through the hybrid coupler Cp2.

As illustrated in FIG. 5, in the first transmission mode, the amplifiers DA4 and DA7 are set to the driven state while the amplifiers DA5 and DA6 are set to the non-driven state. Accordingly, the signal of a phase of −90° is inputted into the amplifier FA1 and the signal of a phase of 0° is inputted into the amplifier FA2. In other words, in the first transmission mode, the phase adjustment circuit 110 adjusts the phases so that the phase of the signal inputted into the amplifier FA1 is delayed from the phase of the signal inputted into the amplifier FA2 by 90°. As illustrated in FIG. 5, the signal inputted into the amplifier FA2 passes through the line Ln1 after being amplified and, thus, the phase is delayed by 90°. In other words, after passing through the line Ln1, the signal outputted from the amplifier FA1 and the signal outputted from the amplifier FA2 are in phase with each other to be combined.

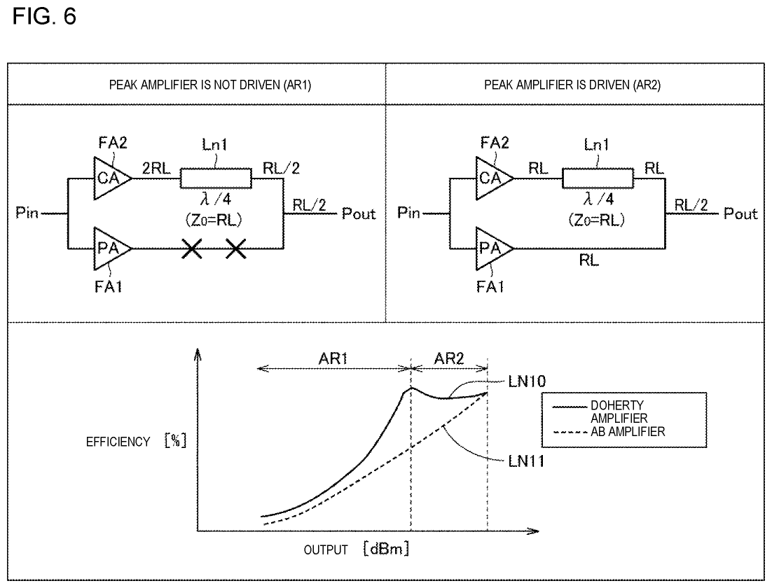

Summary of the Doherty amplifier will now be described. FIG. 6 includes diagrams for describing the operation of the Doherty amplifier. The Doherty amplifier schematically has a configuration in which the amplifier FA2 functioning as the carrier amplifier and the amplifier FA1 functioning as the peak amplifier are connected in parallel between the terminal T1 and the terminal T3 and the line Ln1 functioning as the impedance inverter is disposed between the output terminal of the amplifier FA2 and the output terminal of the amplifier FA1, as illustrated in FIG. 5. The amplifier FA2 operates when output power is low and both the amplifiers FA1 and FA2 operate when the output power is made higher than or equal to a predetermined value.

Referring to FIG. 6, the circuit states when the amplifier FA1 functioning as the peak amplifier is in the driven state (a right-side diagram) and when the amplifier FA1 is in the non-driven state (a left-side diagram) and load impedance are illustrated in its upper portion and the relationship between the output power and efficiency is illustrated in its lower portion. The impedance values when the load impedance of the antenna ANT is set to RL/2 are indicated in the upper portion of FIG. 6.

When both the amplifiers FA2 and FA1 operate (at the right-side diagram in the upper portion), the load impedance when viewed from each of the amplifiers FA2 and FA1 is RL and the load impedance at the combination point is RL/2. In contrast, when the amplifier FA1 is turned off (at the left-side diagram in the upper portion), the load impedance when viewed from the amplifier FA2 is 2RL through the line Ln1 functioning as the impedance inverter.

In general, in the amplifier, the efficiency tends to be increased as the load impedance is increased. Accordingly, as illustrated in the graph in the lower portion, when the Doherty amplifier indicated as a line LN10 is used, it is possible to improve the efficiency with the increasing load impedance in an area AR1 in which the amplifier FA1 is turned off and to improve the efficiency owing to the parallel operation of the amplifier FA2 and the amplifier FA1 in an area AR2 in which the amplifier FA1 is turned on, compared with the case of the AB amplifier capable of outputting the same peak power, illustrated as a line LN11.

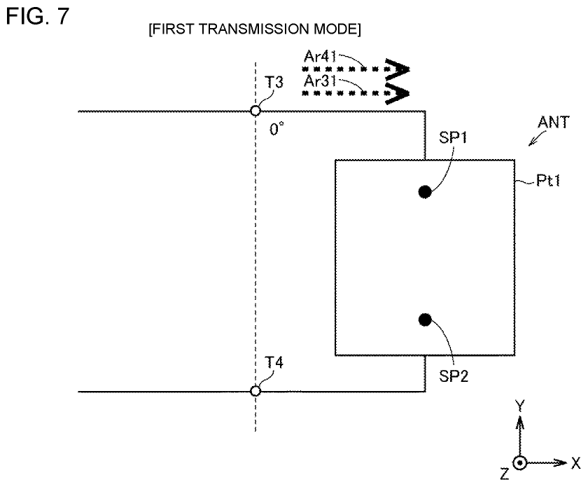

FIG. 7 is a diagram for describing the transmission of the radio waves in the first transmission mode. As illustrated by arrows Ar31 and Ar41, the signals outputted from the amplifiers FA1 and FA2 are supplied to the feeding point SP1 after being adjusted so as to have the same phase and being combined and are outputted as the radio waves. As described above, in the radio-frequency module 10 of the first embodiment, since the impedance is adjusted using the switches that are not provided on the transmission path of the signal by appropriately setting the phase of the output signal from each amplifier and/or the driving state of each amplifier and the conducting state of each switch in the transmission and the reception, it is possible to appropriately switch between the transmission operation and the reception operation. Accordingly, in the radio-frequency module that performs the transmission and the reception using the common antenna, it is possible to keep the isolation between the transmission circuit and the reception circuit. In addition, in the radio-frequency module 10 of the first embodiment, the use of the Doherty amplifier improves the efficiency. Furthermore, since the radio waves received as the differential signals are capable of being inputted into the reception circuit in the same phase in the reception mode in the radio-frequency module 10 of the first embodiment, as described above with reference to FIG. 3 and FIG. 4, it is possible to improve the reception efficiency.

The case is described in the above example, in which the phase adjustment circuit 110 sets the amplifiers DA4 and DA7 to the driven state and sets the amplifiers DA5 and DA6 to the non-driven state to adjust the phases so that the phase of the signal inputted into the amplifier FA1 is delayed from the phase of the signal inputted into the amplifier FA2 by 90°. However, in an aspect, the phase adjustment circuit 110 may set the amplifiers DA5 and DA6 to the driven state and sets the amplifiers DA4 and DA7 to the non-driven state to adjust the phases so that the phase of the signal inputted into the amplifier FA1 is delayed from the phase of the signal inputted into the amplifier FA2 by 90°. Accordingly, even if one of the amplifiers DA4 to DA7 fails, it is possible to realize the driving in the first transmission mode by changing the combination of the amplifiers DA to be driven. In other words, the availability of the radio-frequency module 10 is improved.

### Second Transmission Mode

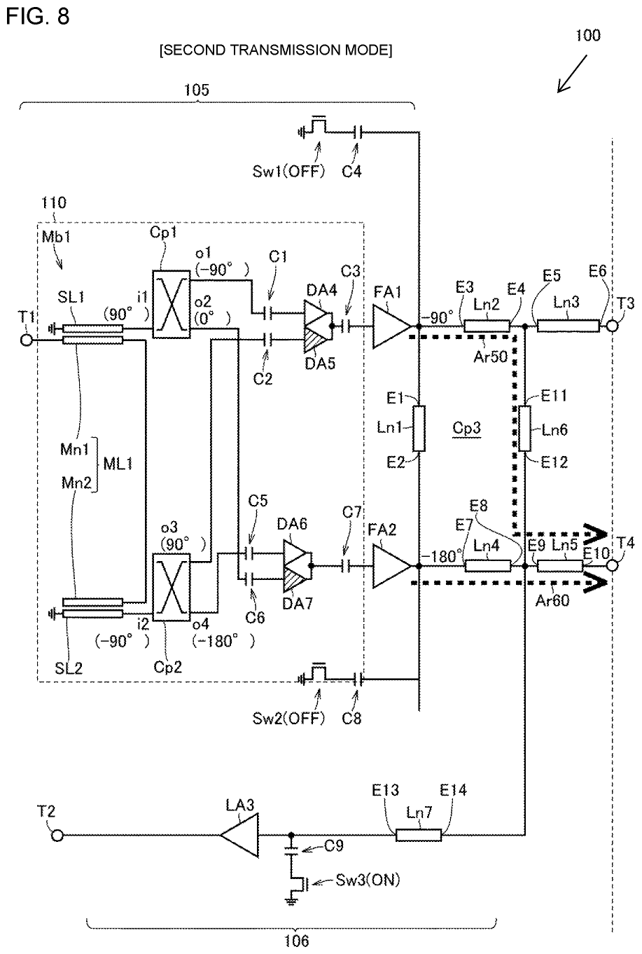

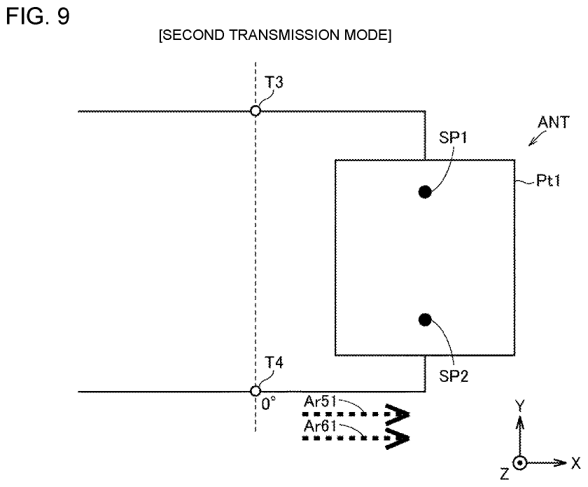

The second transmission mode will now be described with reference to FIG. 8 and FIG. 9. FIG. 8 is a diagram for describing the signal path in the second transmission mode. In the radio-frequency module 10, in the second transmission mode, each of the switches Sw1 and Sw2 is controlled so as to be in the non-conducting state while the switch Sw3 is controlled so as to be in the conducting state. The amplifiers DA4 and DA6 are controlled so as to be in the driven state while the amplifiers DA5 and DA7 are controlled so as to be in the non-driven state. With this configuration, in the second transmission mode, the radio waves are capable of being transmitted with the output from each of the amplifiers FA1 and FA2 being maximized. When the amplifiers FA1 and FA2 are not caused to function as the Doherty amplifiers and the output from each of the amplifiers FA1 and FA2 is maximized, it is possible to stably output the signal, compared with a case in which the output is maximized in the Doherty amplifier.

The transition of the phase of the signal and the transmission path in the second transmission mode will now be described. As illustrated in FIG. 8, in the second transmission mode, the amplifiers DA4 and DA6 are set to the driven state while the amplifier DA5 and DA7 are set to the non-driven state. Accordingly, the signal of a phase of −90° is inputted into the amplifier FA1 and the signal of a phase of −180° is inputted into the amplifier FA2. In other words, in the second transmission mode, the phase adjustment circuit 110 adjusts the phases so that the phase of the signal inputted into the amplifier FA1 advances from the phase of the signal inputted into the amplifier FA2 by 90°.

The line Ln7 is connected in series between the end portion E8 and the ground potential. Accordingly, when the switch Sw3 connected to the ground potential is controlled so as to be in the conducting state, the impedance when the line Ln7 side is viewed from the end portion E8 is in the open state through the line Ln7. In other words, the transmission signal outputted from the output terminal of the amplifier FA2 is inhibited from being transmitted from the output terminal of the amplifier FA2 to the line Ln7 and is prompted to be transmitted to the lines Ln4 and Ln5, as illustrated by an arrow Ar60. Similarly, the transmission signal outputted from the output terminal of the amplifier FA1 is inhibited from being transmitted to the line Ln7 and is prompted to be transmitted from the line Ln6 to the line Ln5, as illustrated by an arrow Ar50.

The phase of the transmission signal outputted from the output terminal of the amplifier FA2 is delayed by 180° due to the passing through the lines Ln4 and Ln5. In other words, the transmission signal outputted from the output terminal of the amplifier FA2 is inputted into the terminal T4 as the signal of a phase of 0°. The phase of the transmission signal outputted from the output terminal of the amplifier FA1 is delayed by 270° due to the passing through the lines Ln2, Ln6, and Ln5, as illustrated by the arrow Ar50. In other words, the transmission signal outputted from the output terminal of the amplifier FA1 is also inputted into the terminal T4 as the signal of a phase of 0°. Accordingly, the transmission signal outputted from the output terminal of the amplifier FA1 is in phase with the transmission signal outputted from the output terminal of the amplifier FA2 to be combined with the transmission signal outputted from the output terminal of the amplifier FA2 at the terminal T4.

The phase of the transmission signal outputted from the output terminal of the amplifier FA2 is delayed by 180° due to the passing through the lines Ln4 and Ln6, although not illustrated by an arrow. In other words, the transmission signal outputted from the output terminal of the amplifier FA2 is inputted into the end portion E5 as the signal of a phase of 0°. In contrast, the phase of the transmission signal outputted from the output terminal of the amplifier FA1 is also delayed by 90° due to the passing through the line Ln2. In other words, the transmission signal outputted from the output terminal of the amplifier FA1 is inputted into the end portion E5 as the signal of a phase of −180°. The phase of the transmission signal outputted from the output terminal of the amplifier FA1 is opposite to the phase of the transmission signal outputted from the output terminal of the amplifier FA2 at the end portion E5. Accordingly, on the line Ln3, the signals of the opposite phases are offset and no signal is practically inputted into the terminal T3.

FIG. 9 is a diagram for describing the transmission of the radio waves in the second transmission mode. As illustrated by arrows Ar51 and Ar61, the signals outputted from the amplifiers FA1 and FA2 are supplied to the feeding point SP2 after being adjusted so as to have the same phase and being combined and are outputted as the radio waves. As described above, in the radio-frequency module 10 of the first embodiment, it is possible to switch the transmission mode by appropriately controlling the driving states of the amplifiers DA4 to DA7 and the conducting state of the switch Sw3.

The case is described in the above example, in which the phase adjustment circuit 110 sets the amplifiers DA4 and DA6 to the driven state and sets the amplifiers DA5 and DA7 to the non-driven state to adjust the phases so that the phase of the signal inputted into the amplifier FA1 advances from the phase of the signal inputted into the amplifier FA2 by 90°. However, in an aspect, the phase adjustment circuit 110 may set the amplifiers DA5 and DA7 to the driven state and sets the amplifiers DA4 and DA6 to the non-driven state to adjust the phases so that the phase of the signal inputted into the amplifier FA1 advances from the phase of the signal inputted into the amplifier FA2 by 90°.

### Processing in Signal Processing Circuit

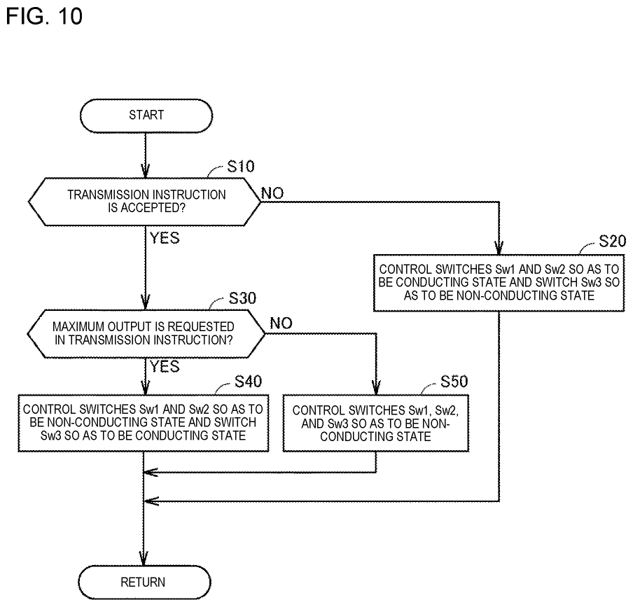

FIG. 10 is a diagram illustrating a flowchart of a process performed in the signal processing circuit 300. The flowchart illustrated in FIG. 10 is realized by the signal processing circuit 300 included in the communication apparatus 1, which performs the process.

In Step S10, the signal processing circuit 300 determines whether an instruction to transmit the transmission signal is accepted. If the instruction to transmit the transmission signal is not accepted (NO in Step S20), in Step S20, the signal processing circuit 300 controls the switches Sw1 and Sw2 so as to be in the conducting state and controls the switch Sw3 so as to be in the non-conducting state. Then, the process in FIG. 10 is terminated. In other words, the radio-frequency module 10 moves to the reception mode. In the reception mode, the radio-frequency module 10 is capable of receiving the radio waves using the antenna ANT.

If the instruction to transmit the transmission signal is accepted (YES in Step S10), in Step S30, the signal processing circuit 300 determines whether the maximum output is requested in the transmission instruction. If the maximum output is not requested in the transmission instruction (NO in Step S30), in Step S50, the signal processing circuit 300 controls each of the switches Sw1, Sw2, and Sw3 so as to be in the non-conducting state. Then, the process in FIG. 10 is terminated. In other words, the radio-frequency module 10 moves to the first transmission mode. In the first transmission mode, the radio-frequency module 10 is capable of efficiently transmitting the radio waves as the Doherty amplifier.

If the maximum output is requested in the transmission instruction (YES in Step S30), in Step S40, the signal processing circuit 300 controls the switches Sw1 and Sw2 so as to be in the non-conducting state and controls the switch Sw3 so as to be in the conducting state. Then, the process in FIG. 10 is terminated. In other words, the radio-frequency module 10 moves to the second transmission mode. In the second transmission mode, the radio-frequency module 10 is capable of causing the amplifiers FA1 and FA2 to be driven at the maximum output in the stable state.

The “amplifier FA1”, the “amplifier FA2”, the “low-noise amplifier LA3”, the “amplifier DA4”, the “amplifier DA5”, the “amplifier DA6”, and the “amplifier DA7” in the first embodiment correspond to a “first amplifier”, a “second amplifier”, a “third amplifier”, a “fourth amplifier”, a “fifth amplifier”, a “sixth amplifier”, and a “seventh amplifier”, respectively, in the present disclosure. The “terminal T1 to the terminal T4” in the first embodiment correspond to “first to fourth terminals”, respectively, in the present disclosure. The “lines Ln1 to Ln7” in the first embodiment correspond to “first transmission line to seventh transmission line”, respectively, in the present disclosure.

The embodiment disclosed here is only an example in all the points and should be considered not to be restrictive. The scope of the present disclosure is indicated not by the above description but by the scope of the claims. The meaning equivalent to the scope of the claims and all the modifications in the scope are intended to be included in the present disclosure.

What is claimed is:

1. A radio-frequency module configured to perform transmission and reception of a signal via an antenna, the radio-frequency module comprising:
a first terminal and a second terminal;
a third terminal and a fourth terminal, which are configured to connect to the antenna;
a first amplifier having an input terminal electrically connected to the first terminal;
a second amplifier having an input terminal electrically connected to the first terminal;
a third amplifier having an output terminal connected to the second terminal;
a first transmission line which is configured to connect between an output terminal of the first amplifier and an output terminal of the second amplifier, and which has a length equal to ¼ of a wavelength of the signal;
a second transmission line which is configured to connect to the output terminal of the first amplifier, and which has a length equal to ¼ of the wavelength of the signal;
a third transmission line which has a first end connected to the second transmission line and a second end connected to the third terminal, and which has a length equal to ½ of the wavelength of the signal;
a fourth transmission line which is configured to connect to the output terminal of the second amplifier, and which has a length equal to ¼ of the wavelength of the signal;
a fifth transmission line which has a first end connected to the fourth transmission line and a second end connected to the fourth terminal, and which has a length equal to ¼ of the wavelength of the signal;
a sixth transmission line which is configured to connect between the first end of the third transmission line and the first end of the fifth transmission line, and which has a length equal to ¼ of the wavelength of the signal;
a seventh transmission line which is configured to connect between an input terminal of the third amplifier and the first end of the fifth transmission line, and which has a length equal to ¼ of the wavelength of the signal;
a first switch configured to connect between the output terminal of the first amplifier and ground; and
a second switch configured to connect between the output terminal of the second amplifier and ground.

2. The radio-frequency module according to claim 1,
wherein the radio-frequency module has, as operation modes, a first transmission mode in which a signal outputted from each of the first amplifier and the second amplifier is outputted to the third terminal, and a reception mode in which a signal supplied from each of the third terminal and the fourth terminal is supplied to the input terminal of the third amplifier,
wherein, in the first transmission mode, the first switch and the second switch are in a non-conducting state, and
wherein, in the reception mode, the first switch and the second switch are in a conducting state.

3. The radio-frequency module according to claim 2, wherein the first amplifier, the second amplifier, and the first transmission line constitute a Doherty amplifier.

4. The radio-frequency module according to claim 2, further comprising:
a third switch configured to connect between the input terminal of the third amplifier and ground,
wherein, in the first transmission mode and the reception mode, the third switch is in a non-conducting state.

5. The radio-frequency module according to claim 4,
wherein the radio-frequency module further has, as an operation mode, a second transmission mode in which the signal outputted from each of the first amplifier and the second amplifier is outputted to the fourth terminal, and
wherein, in the second transmission mode, the first switch and the second switch are in the non-conducting state and the third switch is in a conducting state.

6. The radio-frequency module according to claim 5, further comprising:
a phase adjustment circuit configured to adjust phases of the signals supplied to the first amplifier and the second amplifier,
wherein, in the first transmission mode, a phase of the signal supplied to the second amplifier is 90° ahead of a phase of a signal supplied to the first amplifier, and
wherein, in the second transmission mode, the phase of the signal supplied to the second amplifier is 90° behind the phase of the signal supplied to the first amplifier.

7. The radio-frequency module according to claim 6,
wherein, when the signal outputted from each of the first amplifier and the second amplifier is outputted to the third terminal, each of the first switch, the second switch, and the third switch is in the non-conducting state, and the radio-frequency module is controlled so as to operate in the first transmission mode by the phase adjustment circuit, and
wherein, when the signal outputted from each of the first amplifier and the second amplifier is outputted to the fourth terminal, each of the first switch and the second switch is in the non-conducting state while the third switch is in the conducting state, and the radio-frequency module is controlled so as to operate in the second transmission mode by the phase adjustment circuit.

8. The radio-frequency module according to claim 6,
wherein the phase adjustment circuit comprises
a balun comprising an unbalanced line connected to the first terminal, and first and second balanced lines coupled to the unbalanced line,
a first hybrid coupler having an input terminal connected to the first balanced line of the balun, a first output terminal, and a second output terminal,
a second hybrid coupler having an input terminal connected to the second balanced line of the balun, a third output terminal, and a fourth output terminal,
a fourth amplifier having an input terminal connected to the first output terminal,
a fifth amplifier having an input terminal connected to the third output terminal,
a sixth amplifier having an input terminal connected to the fourth output terminal, and
a seventh amplifier having an input terminal connected to the second output terminal,
wherein the fourth amplifier and the fifth amplifier are connected to the input terminal of the first amplifier, and
wherein the sixth amplifier and the seventh amplifier are connected to the input terminal of the second amplifier.

9. The radio-frequency module according to claim 8,
wherein a phase of a signal outputted from the second output terminal is 90° ahead of a phase of a signal outputted from the first output terminal,
wherein a phase of the signal outputted from the third output terminal is 90° ahead of the phase of the signal outputted from the second output terminal,
wherein a phase of a signal outputted from the fourth output terminal is 90° ahead of the phase of the phase of the signal outputted from the third output terminal,
wherein, in the first transmission mode, the fifth amplifier and the sixth amplifier are in a non-driven state while the fourth amplifier and the seventh amplifier are in a driven state, and
wherein, in the second transmission mode, the fifth amplifier and the seventh amplifier are in the non-driven state while the fourth amplifier and the sixth amplifier are in the driven state.

10. A communication apparatus comprising:
the radio-frequency module according to claim 1; and
the antenna having a plate shape,
wherein a first feeding point and a second feeding point are provided in the antenna at positions offset from a center of the antenna in opposite directions,
wherein the third terminal is connected to the first feeding point, and
wherein the fourth terminal is connected to the second feeding point.

11. The communication apparatus according to claim 10, further comprising:
a feed circuit configured to supply the signal to the first terminal of the radio-frequency module.

12. A control method used in a radio-frequency module that performs transmission and reception of a signal via an antenna,
wherein the radio-frequency module comprises:
a first terminal and a second terminal,
a third terminal and a fourth terminal, which are configured to connect to the antenna,
a first amplifier having an input terminal electrically connected to the first terminal,
a second amplifier having an input terminal electrically connected to the first terminal,
a third amplifier having an output terminal connected to the second terminal,
a first transmission line which is configured to connect between an output terminal of the first amplifier and an output terminal of the second amplifier, and which has a length equal to ¼ of a wavelength of the signal,
a second transmission line which is configured to connect to the output terminal of the first amplifier, and which has a length equal to ¼ of the wavelength of the signal,
a third transmission line which has a first end connected to the second transmission line and a second end connected to the third terminal, and which has a length equal to ½ of the wavelength of the signal,
a fourth transmission line which is configured to connect to the output terminal of the second amplifier, and which has a length equal to ¼ of the wavelength of the signal,
a fifth transmission line which has a first end connected to the fourth transmission line and a second end connected to the fourth terminal, and which has a length equal to ¼ of the wavelength of the signal,
a sixth transmission line which is configured to connect between the first end of the third transmission line and the first end of the fifth transmission line, and which has a length equal to ¼ of the wavelength of the signal,
a seventh transmission line which is configured to connect between an input terminal of the third amplifier and the first end of the fifth transmission line, and which has a length equal to ¼ of the wavelength of the signal,
a first switch configured to connect between the output terminal of the first amplifier and ground, and
a second switch configured to be connected between the output terminal of the second amplifier and ground, the control method comprising:
setting each of the first switch and the second switch to a conducting state when the signal supplied from each of the third terminal and the fourth terminal is supplied to the input terminal of the third amplifier; and
setting each of the first switch and the second switch to a non-conducting state when the signal outputted from each of the first amplifier and the second amplifier is outputted to the third terminal.
